(19) United States
(12) Patent Application Publication
(10) Pub. No.: US 2026/0265918 A1
(43) Pub. Date: Sep. 10, 2026

(54) SECONDARY TRANSLATING SUSCEPTOR FOR SUPERCONDUCTOR MANUFACTURING

(71) Applicant: METOX TECHNOLOGIES, INC, Houston, TX (US)

(72) Inventor: Christopher SHAY, Horseshoe Bay, TX (US)

(21) Appl. No.: 18/871,677

(22) PCT Filed: Jul. 10, 2023
(86) PCT No.: PCT/US2023/027216

§ 371 Date: Dec. 4, 2024

Related U.S. Application Data
(60) Provisional application No. 63/388,515, filed on Jul. 12, 2022.

(51) Int. Cl. C23C 16/458; C23C 16/18; C23C 16/44; C23C 16/455; C23C 16/48; C23C 16/54; H10P 72/00

(52) U.S. Cl. CPC C23C 16/4586; C23C 16/4412; C23C 16/45565; C23C 16/481; C23C 16/482; C23C 16/545; H10P 72/0402; C23C 16/18

(57) ABSTRACT

A multi-part susceptor assembly used in a deposition reactor provides heat input and controls the temperature of a substrate tape as well as minimizes the build-up of errant deposition material. The susceptor heats a substrate tape within the reactor upon which one or more thin films are deposited, particularly high temperature superconductor (HTS) thin films produced in a MOCVD reactor.

### CROSS REFERENCE TO RELATED APPLICATIONS

This application is a national stage application from PCT application PCT/US23/27216 filed Jul. 10, 2023, entitled “Secondary Translating Susceptor Apparatus, System and Method” which claims priority and benefit from U.S. Provisional Patent Application No. 63/388,515 filed on Jul. 12, 2022, also entitled “Secondary Translating Susceptor Apparatus, System and Method,” the contents of both of which are incorporated in their entirety herein by reference.

### BACKGROUND OF THE INVENTION

### Technical Field

Embodiments of the subject matter disclosed herein generally relate to susceptor assemblies and systems utilizing said susceptors in a deposition reactor and more particularly in vapor deposition reactors for fabricating high-temperature superconductors on substrate tapes.

### Discussion of the Background

High temperature superconductors (HTS) provide the potential for development of superconductor components that perform at higher operating temperatures compared to traditional superconductors that operate at liquid helium temperature (4.2 K). Superconductors operating at the higher temperatures thus provide the ability to develop superconducting components and products more economically. Thin film HTS material comprised of YBa₂Cu₃O₇₋ₓ (YBCO), is one of a group of oxide-based superconductors. After the initial discovery of YBCO superconductors, other superconducting materials were discovered having a similar chemical composition but with Y replaced by other rare earth (RE) elements. This family of superconductors is often denoted as REBCO where RE may include Y, La, Nd, Sm, Eu, Gd, Tb, Dy, Ho, Er, Tm, Yb or Lu. This material formed the basis for second generation or “2G” HTS wire technology which provides a more cost-effective material for manufacturing HTS tapes and wires.

Such HTS films are typically deposited as textured REBCO thin films which may include one or more buffer layers onto an atomically textured metal substrate. In the case of MOCVD, an organic ligand may comprise a vapor phase precursor delivered to the substrate for deposition. In the manufacturing of High Temperature Superconductors (HTS) via chemical vapor deposition (CVD) or metal-organic chemical vapor deposition (MOCVD) processing, a stainless steel or Hastelloy substrate tape is heated to high temperature, for example, 800° C. to 900° C. for the vapor phase precursor materials to deposit on the substrate tape and HTS film growth to occur.

There are different devices and methods for heating a substrate tape, including IR lamps that heat the tape via radiation, and hot block susceptors that directly contact the substrate tape and provide the needed heat via conduction. A typical CVD reactor apparatus 100 is shown in FIG. 1 and includes using a single stationary hot block type susceptor 110 that supports and heats a translating substrate tape 120. Reactor housing 190 is maintained at vacuum via an outlet port 130 and precursor reactant(s) 140 are introduced via a showerhead 150.

Existing heated susceptors in a CVD process particularly for HTS production have several disadvantages including high temperature gradients within the reactor, and errant deposition 180 that builds up on the exposed surfaces of the susceptor and other components of the reactor. One limitation to achieving desirable thermal control is that the spacing between the showerhead and the deposition surface may be very small, for example 5 mm to 30 mm, making it difficult to illuminate the deposition surface to the high intensity levels required for the process. The surface of the showerhead may be e.g., 300-350° C., while the surface of the deposition area may typically be around 850-900° C., making for very high temperature gradients of, for example, 500° C. or more over the small gap between the showerhead and the top of the susceptor.

Compounding the temperature control challenges, is that cooler precursor and carrier gases flowing from the showerhead may cool both the susceptor and substrate. The deposition process is thus very sensitive to temperature gradients and are preferably maintained within approximately a 5-10° C. range of a target substrate temperature for acceptable deposition performance.

In a typical MOCVD HTS process, the reactant precursor gases tend to deposit upon other surfaces within the reactor chamber where the surface temperature is above approx. 400-450° C. To keep the chamber clean, it is thus critical to maintain internal surfaces at a minimum, or at least below, approximately 400° C. to prevent errant deposition which is deposition occurring on surfaces other than the intended substrate. Particularly in CVD reactors under vacuum, precursor vapor undergoes expansion and is thus prone to deposit on exposed surfaces of the susceptor outside the intended target deposition zone on the tape where HTS film growth is desired. Over long process times, the errant material deposited on the susceptor may build up to exceed the tape thickness that may be between 30 to 100 micrometers (um) thickness, for example. Such errant deposition buildup on susceptor surfaces near the tape edges themselves can cause degradation of the properties of the HTS film grown on the tape. For example, the precursor boundary layer flow uniformity on and around the tape may be impacted by errant deposition, e.g., the heat transfer and the radiation properties of the errant material build-up may be different than the HTS film which can cause local edge temperature non-uniformity on the tape; and/or the built-up material itself may break away, become entrained within micro-eddies, and redeposit on and foul or disturb the deposited layers causing performance degradation of the HTS film.

Finally, errant material build-up on the susceptor is a major limiting factor in the ability to run continuous and lengthy HTS process runs. For example, the build-up may prevent the system from processing kilometers long HTS tapes due to a need to stop processing and disassemble the reactor for cleaning. For these reasons, new susceptor assemblies and systems are needed to tightly control thermal conditions as well as errant deposition particularly in areas proximal to the target substrate tape.

### SUMMARY OF EXAMPLE EMBODIMENTS

According to an embodiment, there is a susceptor assembly for heating and temperature control of a substrate tape within a deposition reactor that includes a primary susceptor; a secondary susceptor disposed between the primary susceptor and the longitudinal substrate tape, and wherein the secondary susceptor is configured as a longitudinal tape having a width greater than a substrate tape.

According to another embodiment, there is a susceptor assembly for heating and temperature control of a substrate tape within a deposition apparatus that includes a primary susceptor comprised of two or more adjacent raised sections configured to heat a separate longitudinal substrate tape and adjacent raised sections form a channel to collect errant deposition material from between adjacent longitudinal substrate tapes; a secondary susceptor disposed between the primary susceptor and the longitudinal substrate tape, and wherein the secondary susceptor is configured as a longitudinal tape having a width greater than a substrate tape,

According to yet another embodiment, there is a chemical vapor deposition apparatus for deposition of thin films on a longitudinal substrate tape that includes a reactor housing having an inlet showerhead, a vacuum exhaust, and an illumination source. A susceptor assembly is also located within the reactor housing and includes a primary susceptor for heating at least one longitudinal substrate tape, a secondary susceptor disposed between the primary susceptor and the longitudinal substrate tape, and wherein the secondary susceptor is configured as a longitudinal tape having a width greater than a longitudinal substrate tape and the primary susceptor is stationary and the secondary susceptor translates in a lengthwise direction relative to the longitudinal substrate tape, and further wherein the longitudinal substrate tape is configured to translate above the secondary susceptor and below the inlet showerhead.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 shows a prior art reactor assembly with a hot block type susceptor.

FIG. 2 shows an exemplary susceptor assembly with a primary susceptor and a secondary moving susceptor.

FIGS. 3A and 3B show two views of an exemplary susceptor assembly to process more than one substrate tape.

FIG. 4 shows an exemplary an exemplary susceptor assembly to process multiple passes of a single substrate tape.

FIG. 5 shows an exemplary susceptor assembly with a primary susceptor and a secondary moving susceptor also including refractory elements and radiation shields.

FIG. 6 shows an exemplary susceptor assembly wherein the primary susceptor also includes raised sections and collection channels.

FIGS. 7A and 7B show detail of susceptor raised sections and collection channels.

FIG. 8 shows additional detail of susceptor raised sections and collection channels that includes micro-protrusions.

FIG. 9 shows and exemplary CVD reactor apparatus utilizes the susceptor assemblies that include a primary stationary and a secondary moving susceptor.

### DETAILED DESCRIPTION OF EXAMPLES OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to susceptor assemblies and systems for deposition of thin films, particularly superconducting coated conductors, formed from films deposited on substrate tapes in a CVD and more particularly in a MOCVD reactor. However, the embodiments discussed herein are not limited to such elements. For example, the susceptor assemblies disclosed herein have application to other reactor types that utilize a susceptor for heating a substrate of any type, and where build-up or errant deposition may be a problem. Such other reactor types may include, but are not limited to, Pulsed Laser Deposition (PLD), Rotating Cylinder Reactor (RCE) and others.

Reference throughout the specification to “one embodiment” or “an embodiment” means that a particular feature, structure, or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. The drawings are intended to be illustrative of the claimed features and unless stated otherwise are not to scale. Where a dimension of a given feature may be pertinent, the detailed description will indicate one or more examples of the range and units of said dimension where needed to enable the subject matter. Further, the described features, structures or characteristics may be combined in any suitable manner in one or more embodiments.

This disclosure describes various embodiments of a susceptor assembly that includes a secondary moving susceptor that continuously provides a clean surface under the substrate tape, and certain other embodiments, also surfaces and areas adjacent to the substrate tape. The moving susceptor typically is comprised of a metal tape (typically a Hastelloy tape) that has a width at least equal to and preferably greater than the width of the substrate tape. In preferred embodiments, the metal longitudinal substrate tape (i.e., the process tape upon which the desired HTS layer is to be deposited) translates over and in contact with the moving susceptor thus the moving susceptor travels underneath the substrate tape.

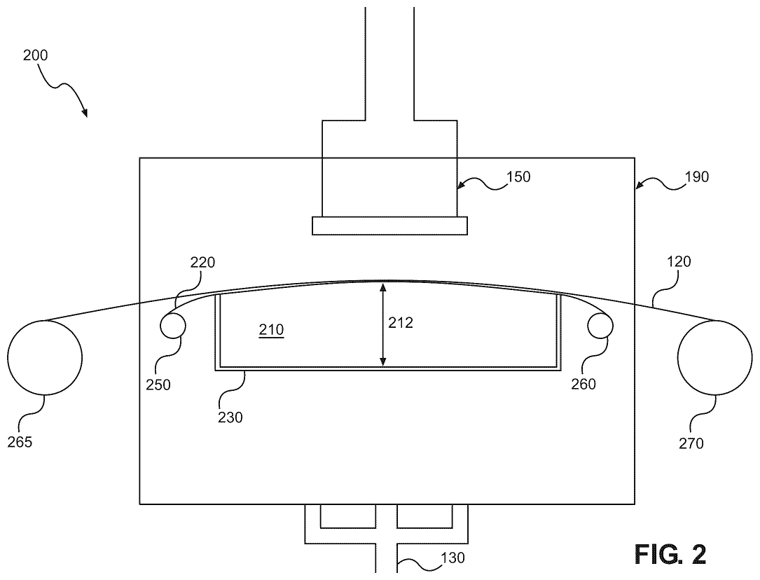

An exemplary susceptor assembly 200 is illustrated in sideview in FIG. 2. Susceptor assembly 200 is located inside reactor housing 190 which also includes a showerhead 150 and a vacuum exhaust 130. Susceptor assembly 200 includes a primary stationary susceptor block 210 and secondary moving susceptor 220 for heating and temperature control of a longitudinal substrate tape 120 within the deposition apparatus. Primary susceptor 210 is typically longitudinal in shape and thus has a length approximately equal to the desired deposition zone length within a reactor apparatus and a width equal to or slightly greater than the width of a substrate tape. Hence, the length of the primary susceptor is greater than its width, and typically is a length many times its width, e.g., 5, 10, 20 or more times its width.

Also in this embodiment, a wide tape acts as the secondary moving susceptor 220 and is supplied by one or more feed reels 250 on the left and translates over the primary stationary susceptor 210. Secondary susceptor tape 220 is then taken up by one or more take-up reels 260 on the right as shown. Note that the stationary susceptor 210 may also be referred to interchangeably as the primary susceptor, primary heater or primary heater element, primary susceptor block, fixed susceptor, main susceptor, or lower susceptor. Similarly, the moving susceptor 220 may also be referred to herein as the secondary susceptor, upper susceptor, secondary susceptor tape, or secondary tape. In the embodiments of susceptor assemblies disclosed herein, the term susceptor shall refer to a body of material configured to absorb energy and transmit it to a second body with the intent to provide a target temperature of a body. For example, the first body may absorb electromagnetic energy and convert it to heat which in turn may be transmitted to a second body by conduction or said heat of the first body may be re-emitted as infrared thermal or other wavelength of radiation and transmitted to a second body by radiation heat transfer, or the first body may directly absorb thermal energy and transmit it to another body by conduction.

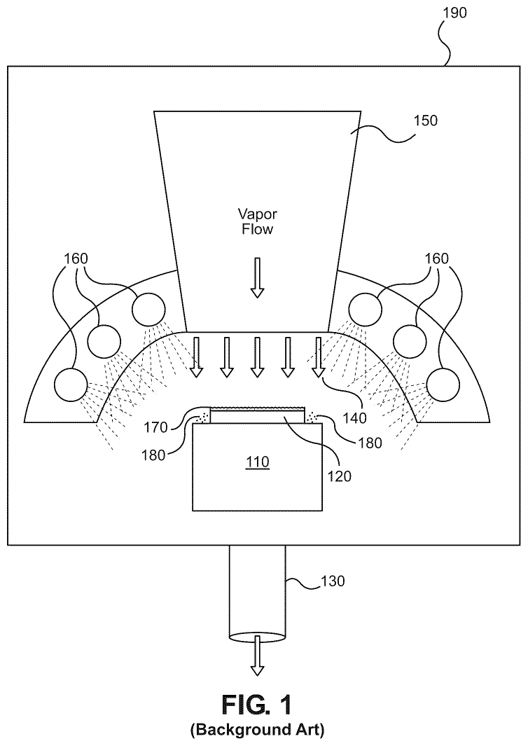

Substrate tape 120 is also fed from one or more feed reels 265 and translates over moving susceptor 220 which in this embodiment is in contact with and translates over the primary stationary susceptor 210 after which substrate tape 120 is taken up by one or more take-up reels 270. In this manner, the susceptor assembly 200 thus comprises a two-part susceptor (210 and 220) which includes an upper moving susceptor 220 in slidable contact with a lower non-moving susceptor 210. Thus, in this embodiment, the primary susceptor 210 may be comprised of a conductive block type susceptor 110 such as that shown in FIG. 1.

As mentioned above, longitudinal substrate tape 120 is typically comprised of a long thin tape wherein the length may be many meters or kilometers in length and the width comparatively narrow, e.g., 10 mm, 12 mm, etc. and may be fabricated from an atomically textured stainless steel or Hastelloy material. The moving susceptor 220 may also be comprised of stainless steel or Hastelloy but may also be composed of any suitably conductive metallic material such as copper, an alloyed metal or a conductive composite. Thus, the same or similar material used for the substrate tape may be used for the moving susceptor tape, but the two tapes may be comprised of different materials or compositions as well.

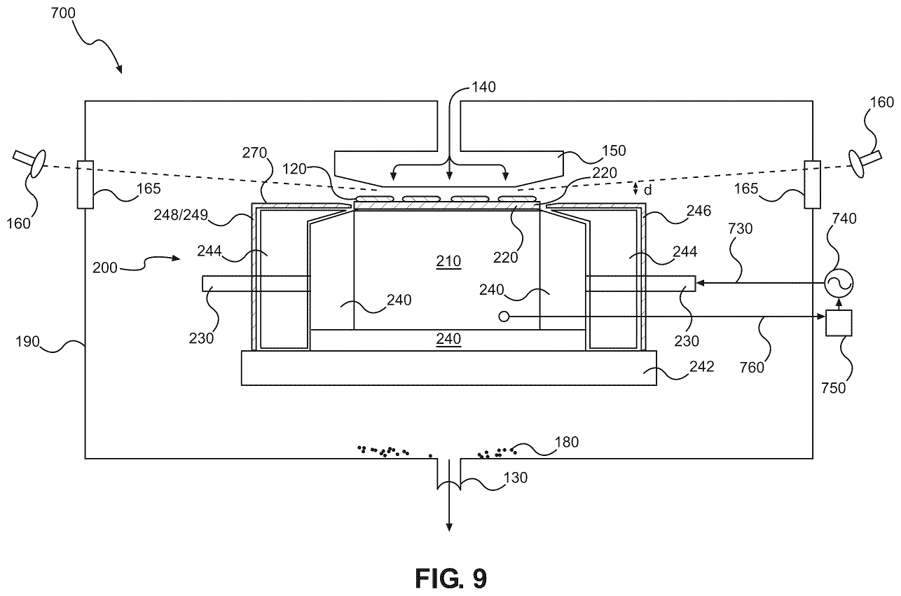

The reactor apparatus (see FIG. 9 below) may also include a mechanism to establish and maintain a desired tension in the secondary moving susceptor tape which helps assure good contact between the moving susceptor 220 and primary susceptor 210 as well as the substrate tape 120. Tensioning elements for the moving susceptor 220 may be comprised of similar tension devices and systems commonly utilized to maintain wire or tape tension such as a spring tensioner or friction wheel built into the feed reel(s) 250/265 and/or take-up reel(s) 260/270. Also, the upper surface of primary (stationary) susceptor block 210 as shown in FIG. 2 may be curved in a lengthwise direction such that the vertical height 212 of the primary susceptor 210 is greater at the center so as to impart tension in both the moving susceptor 220 and the substrate tape 120 to improve contact between the two tapes. A curved primary susceptor 210 may also be used with or without a tensioning device within the reel-to-reel system to further improve tension and contact.

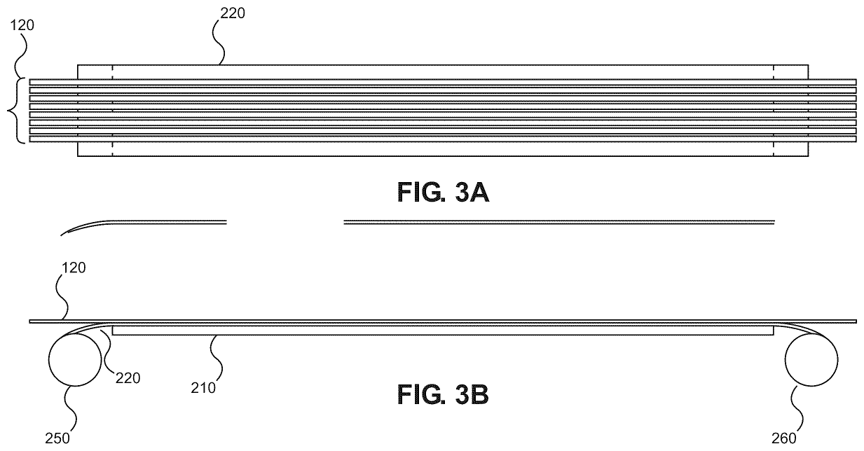

For illustrative purposes, FIG. 3A shows a top-down view and FIG. 3B a side view of an embodiment with eight substrate tapes 120 in contact with a single secondary moving susceptor 220 of susceptor assembly 200. However, any number of substrate tapes is contemplated by the present disclosure. Furthermore, one or more tapes 120 may re-route via a reel-to-reel system through the deposition zone and thus contact susceptor assembly 200 more than once. PCT Patent Application Publication WO2022/182967 owned by the present Applicant entitled, “Multi-Stack Susceptor CVD Reactor for High-Throughput HTS Tape Manufacturing” is incorporated herein for all purposes and discloses several substrate tape routing systems and methods that include, for example, multi-susceptor and multi pass arrangements.

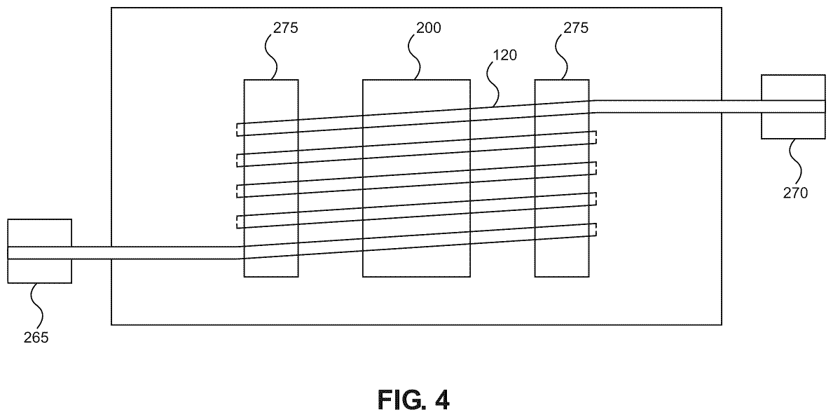

For example, FIG. 4 depicts one embodiment of a multi-pass reel-to-reel system whereby a single substrate tape 120 conducts multiple passes in order to increase deposition throughput and efficiency. In this example, substrate tape 120 is provided by feed reel 265 on the left, translates over susceptor assembly 200 and reverses direction around rollers 275 in order to pass over the susceptor assembly 200 five times. For simplicity, reels 250 and 260 that handle secondary susceptor 220 of assembly 200 are not shown but in this depiction would be located beneath substrate tape 120 and thus fed and taken up by reels 250/260 located inside reversal rollers 275.

Thus, tape handling configurations described herein may encompass a “single-pass” tape configuration, or a single-length tape with “multi-pass” tape configuration, or several separate tapes running in parallel over susceptor assembly 200 in a “multi-track” configuration. The reels or rollers that are used in single or multi-pass configurations may be located inside the reactor, or outside the reactor with the one or more substrate tapes 120 passing through slits or ports in the reactor walls.

In preferred embodiments, moving susceptor 220 may translate at a lower speed (e.g., one-tenth) than the substrate tape 120 translates. A lower moving susceptor tape speed may provide benefits to process efficiency and cost reduction since lower speed may reduce use and lower costs to rework (clean) or replace the moving susceptor tape. For example, the moving tape speed may be one half or less than the speed of the substrate tape speed, but any speed differential or no differential speed may be practiced and fall within the scope of this disclosure. Further, in preferred embodiments, the moving susceptor and substrate tapes may translate in the same direction but alternatively may translate in opposing directions.

Good conductive heat transfer from the susceptor components and the substrate tape 120 depends on consistent contact between the primary stationary susceptor 210 and secondary moving susceptor 220 and between the moving susceptor 220 and ultimately with the substrate tape 120. Thus, it is preferred that these two points of contact between surfaces make consistent contact and each surface be smooth at the macro level, i.e., no bends or perturbations in the tapes. To achieve this, the substrate tape 120 is typically smoothened by electropolishing. A Roughness Average (Ra), a standardized measure of the surface roughness, of a few nm is desirable to minimize the temperature difference between the substrate tape 120 and susceptor components. For example, for SIC primary susceptors 210, electropolishing, mechanical or other suitable polishing techniques may be used. A similar process may be used to smoothen the moving susceptor 220 as well as the stationary susceptor 210 or different techniques for each part of the susceptor assembly may be employed depending on their composition. A high degree of smoothness will also aid in reducing wear and extending the life of the primary stationary susceptor.

For example, the temperature difference between a substrate tape 120 and the susceptor with the tape held in close contact with a single piece susceptor was measured to be 126° C. at a reactor pressure of 5 Torr and an Argon (Ar) atmosphere in an experimental reactor when the tape was at 850° C. and the showerhead at 300° C. Using this information and reasonable assumptions for the emissivities of the substrate tape 120 top and bottom surfaces; the stationary 210 and moving 220 susceptor surfaces and the showerhead surface; the temperature between the substrate tape 120 and the stationary susceptor 210 described herein was estimated to be 236° C. for a substrate tape temperature of 850° C. This value is an exemplary measurement and represents a reasonable delta temperature (delta T) between the surfaces thus enabling the use of a moving susceptor whilst achieving and maintaining adequate substrate temperature.

Even with 236° C. delta T, the stationary susceptor surface 210 temperature (850° C.+236° C.) is reasonable and is achievable with a metal susceptor, and certainly can be achieved with a SIC susceptor. The susceptor roughness in the above example was determined to be in the range of a few microns approximately; however, roughness levels in the e.g., 5-40 nm range will additionally lower the delta T. The delta T is also a function of changes in reactor pressure which permits another controllable factor to achieve a target delta T or max delta T. Increased smoothness between surfaces results in sufficiently low delta T that in tum may partially obviate pressure effects.

In preferred embodiments, moving susceptor 220 has a width that covers the entire upper surface of the stationary susceptor 210 which ensures that there is no errant deposition 180 on the stationary susceptor 210 surfaces. Moreover, the surface of the moving susceptor 220 is continuously renewed via translation thus minimizing contamination of substrate tape 120. Also, the moving susceptor may be a predetermined length that given a desired deposition run time and translation speed, will be expended within the time needed to conduct a single reactor system production run. Alternatively, the tape may be refed in a loop arrangement a set number of times before it is changed out. In yet other embodiments, the moving susceptor system may include a continuous cleaning mode whereby the moving susceptor 220 tape prior or after passage through the deposition zone also passes that a scraping slit or brush apparatus preferably contained within an enclosure to capture the removed particles and debris. The cleaning process may also be located outside the reactor whereby one or more take-up and re-routing reels is located outside the reactor chamber and the moving tape passes back through a narrow slit located within the reactor wall after it is cleaned externally.

Maintaining clean stationary susceptor 210 surfaces during production runs will ensure minimal downtime. Also, the stationary susceptor does not have to be dismantled often which minimizes downtime and the possibility of damaging the stationary susceptor. The speed of the moving susceptor 220 is adjusted so that the errant material deposited on it is sufficiently thin (for example </=5 μm), thus avoiding flaking and generating friable particles or disrupting the flow pattern which could impact the quality of the HTS film on the substrate tape 120. In preferred embodiments, stationary susceptor 210 surface is flat and does not have complex surface geometries that may be difficult and expensive to fabricate and maintain. In addition, the tolerances for a flat simple stationary susceptor and the tape drives necessary for the translation and tensioning systems are simplified.

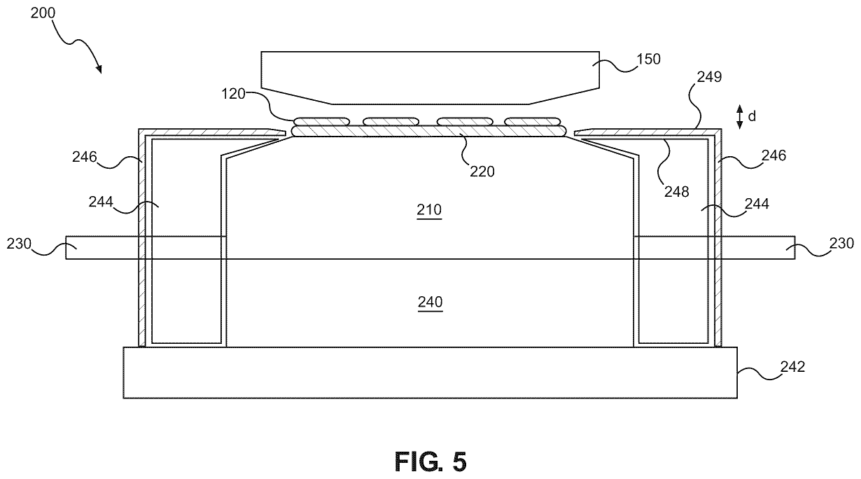

Susceptor assembly 200 may include additional thermal control elements to aid in maintaining a desired temperature profile. PCT Application PCT/US23/13916 owned by the present Applicant entitled, “Susceptor Assembly for a Chemical Vapor Deposition Reactor,” is incorporated herein for all purposes and discloses various shielded susceptor assemblies providing enhanced thermal control features. For example, FIG. 5 shows a 2D cross section (end view) of an exemplary susceptor assembly 200 having refractory and shielding elements.

In certain embodiments, refractory element(s) 240 are disposed adjacent one or more sides of primary susceptor block 210 while leaving an upper opening for secondary susceptor 220. Refractory elements 240 provide both thermal and structural benefits. In this embodiment, refractory elements 240 position and support primary susceptor 210 and a lowermost element 242 provides a base of support for the entire susceptor assembly 200. Optional outside refractory elements 244 may be included to provide an additional insulative layer to innermost elements 240. Thus, in this example, a two-component set of refractory elements 240/244 is utilized whereby one component 240 provides a thermal barrier as well as, owing to its rigidity, e.g., a solid ceramic, they also provide structural support to primary susceptor 210. Outer positioned additional elements 244 provide added insulation and thus may be comprised of a different and lighter material without rigidity, e.g., ceramic wool.

Also shown in FIG. 5, a radiation shield 246 comprised of a single shaped sheet or more than one individual sheet or plates of thin metal, metal alloy or ceramic composition may surround refractory element(s) 240/244 on more than one side, and in certain embodiments, encompasses the entirety of susceptor assembly 200 save the uppermost portion of primary susceptor block 210. Radiation shield 246 may further include a low emissivity coating 248 on the inside surfaces (the side facing the refractory element(s) (240/242/244) and/or a high emissivity coating 249 on the outside surfaces. This shielding reflects heat from the susceptor 210 but cools quickly due to the high emissivity coating 249 on the outside. Though the temperature of the inside of the susceptor assembly 200 may exceed e.g., 1200° C., the temperature of the radiation shield 246 outside surfaces may be substantially less, around 350° C., for example. This reduced external temperature prevents or minimizes errant deposition on the outside of the susceptor assembly 200. Thus, the only surfaces exposed to high temperatures are preferably limited to the deposition surface, i.e., the substrate tape(s) 120.

In certain embodiments, the low emissivity coating 248 may be comprised of a gold or silver coating or an alloy thereof coated on the inside. An exemplary high emissivity coating 249 on the outside may be any vacuum compatible physical vapor deposited black body enhancing coating, e.g., a high temperature black paint.

In other embodiments, more complex stationary (primary) susceptor blocks may be advantageous. U.S. Patent Application US2023/0079651A1 owned by the present Applicant entitled, “Susceptor for a Chemical Vapor Deposition Reactor,” is incorporated herein for all purposes and discloses various embodiments of susceptors for enhanced errant deposition control.

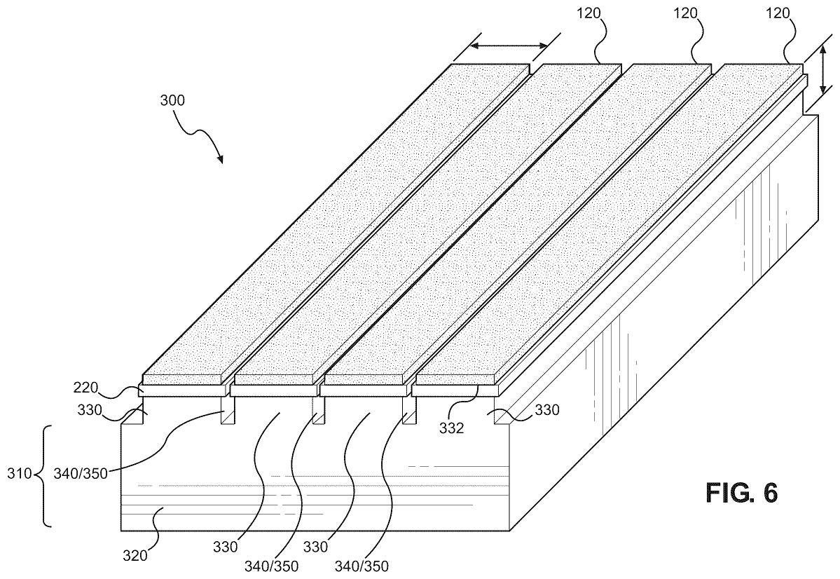

An exemplary susceptor assembly 300 for heating and temperature control of a substrate tape 120 within a deposition apparatus is shown in FIG. 6 having a primary susceptor block 310 comprised of raised sections and channels. In this embodiment, primary susceptor block 310 is comprised of a main body 320 which forms the base of susceptor block 310. As described earlier, susceptor assembly 300 utilizing primary susceptor block 310 may similarly be configured to support more than one substrate tape 120. However, unlike the multi-pass, single tape 120 embodiments shown in FIG. 3 and FIG. 4 whereby a single substrate tape 120 is rerouted to pass over the susceptor more than one time while utilizing a single moving susceptor tape 220; susceptor block 310 is intended to be utilized with multiple moving susceptor tapes 220. In this approach, a single susceptor block 310 is configured to support multiple single pass substrate tapes 120. For simplicity, FIG. 6 depicts a susceptor block 310 to support four substrate tapes 120 and four moving susceptor tapes 220, but any number of substrate tapes is contemplated herein.

Primary susceptor block 310 may similarly be manufactured from any suitable metal or metal alloy such as Inconel that is machinable and has a suitable thermal conductivity, or alternatively may be composed of Silicon Carbide (SIC). Susceptor block 310 may comprise two or more raised sections 330 that extend vertically from main body 320 and extend lengthwise along the length of susceptor 310. Each raised section 330 is separated from an adjacent raised section by a gap 340 that extends downward to a prescribed depth and forms a channel 350. Raised sections 330 are preferably of the same composition as the main body 210 and may be machined, cast or milled from a single block of material. Other approaches may include laser etching or band saw cutting to produce gaps 340. In other embodiments, it is possible to have the raised sections 330 separate from but operably coupled to the main body 320. In this case, the raised sections 330 may be of the same material as main body 320 or it may be of a different material with different thermal conductivity. In this case, the raised sections 330 may be attached to the main body 320 using different methods; examples include screws or bonding compounds. In preferred embodiments, each raised section 330 is shaped with vertical sides thus each section is rectangular in cross section, however, in other embodiments, raised sections 330 may be shaped differently, e.g., trapezoidal. It should be noted that the refractory elements 240/242/244 and radiation shields 246 as described above with reference to primary susceptor block 210 of susceptor assembly 200 are applicable to primary susceptor block 310 of susceptor assembly 300.

The width of the top surface 332 of raised section 330 is preferably the same or less than the width of substrate tape 120. For example, substrate tape 120 may be nominally 12 mm wide, and thus raised section's 330 top surface 332 is 12 mm wide. In other embodiments, raised section's 330 top surface 332 may be slightly less in width, thus in this example, top surface 332 may be 10-11 mm wide. Individual moving susceptors 220 in preferred embodiments may be wider than primary raised sections 330 as well as substrate tape 120. For example, for a 12 mm wide primary raised section 330 and a 12 mm wide substrate tape 120, moving susceptor 220 may have a width of approximately 15 mm. Thus gaps 340 may be machined such that a predetermined spacing between adjacent tapes (e.g., 5 mm) is maintained. In this manner, susceptor assembly 300 contacts and conductively heats multiple substrate tapes 120 without having a portion of top surface 332 exposed and susceptible to build-up of errant deposition 180. Channels 350 thus act to capture additional errant deposition 180 material that may not adhere to moving susceptor 220.

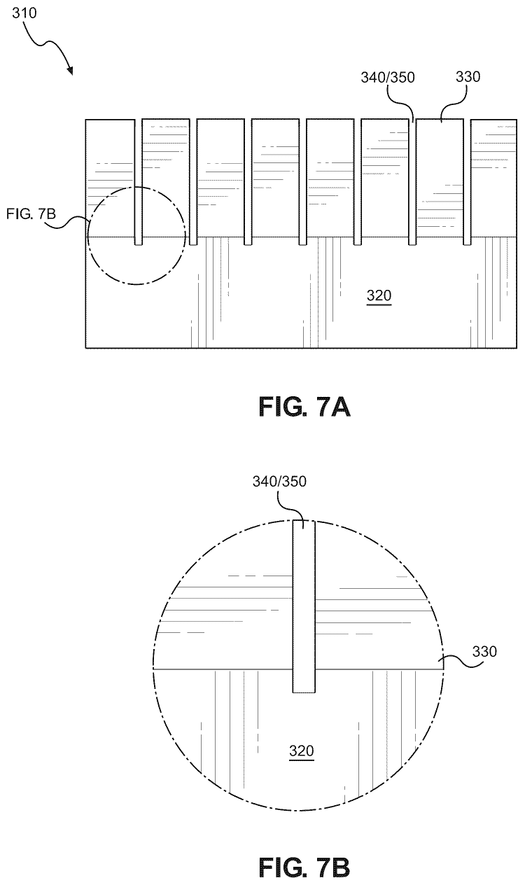

FIGS. 7a and 7b shows an expanded view of primary susceptor block 310 with a gap 340 of 1.5 mm wide and a channel 350 of 10 mm deep. The dimensions of channel 350 may be of greater or less depth, for example, 5 mm or 20 mm or more to accommodate greater volumes of errant deposition material 180 which may accumulate to greater degree depending on run time, deposition efficiency or other reactor design characteristic. Though other dimensions are possible, channels 350 with depths greater than gap 340 widths are preferred, e.g., channel depths four or more times the gap widths are preferred so as to provide greater entrainment of errant particulate material 180. Furthermore, channels may be formed with angled sidewalls in cross-section or other shapes.

The growth mechanism occurring during the deposition of thin films on a substrate tape 120 and a susceptor 210/310 will be discussed in order to describe the operation and benefits of channels 350. With reference to FIG. 9 to be discussed in greater detail later, the precursor chemicals are transported by the main inlet gas flow showerhead 150 to the substrate tape(s) 120 after which the reaction and product deposition occurs chiefly inside the laminar flow boundary layer on and around the substrate. The boundary layer for example may be similar to the boundary layer of flow over a flat plate. Thus, deposition within the laminar boundary layer uniformly deposits particles over the exposed susceptor surfaces between tapes. When channels 350 are added to the susceptor block 310, the laminar flow boundary layer is disturbed with discontinuities at those locations on the susceptor. Another benefit of the channels includes, for example, that particles flowing into a channel get trapped and tend to remain inside the channel in a circulatory motion until they eventually adhere and are deposited upon an interior wall surface of the channel. Hence adding channels 350 to the susceptor aids in the minimization of particle build-up on the susceptor surfaces between tapes which in turn prevents loose particles from potentially fouling the thin film. Thus, the embodiment employing a moving susceptor 220 and channels 350 may work in conjunction to minimize and capture errant deposition material thereby increasing the lifespan of the moving susceptor and also allowing for longer production runtimes.

During long process runtimes, errant deposition material 180 may accumulate in channel 350 to a degree that may fill or nearly fill the channel, and an inert purge gas such argon or nitrogen may be directed along the channel to push material to an end of the susceptor assembly 300 and out towards an outlet of the reactor. Similar to susceptor assembly 200, primary susceptor block 310 top surface 332 may include a curvature in the lengthwise direction to provide tension on substrate tape 120. In this way, the vertical height 212 of a raised section 330 may be greater at the center than at the ends of raised section 330. In the case of raised sections 330 with variable height, channel 350 may be machined such that the channel's depth is a constant depth down the length of the susceptor, for example, follows the curvature of the susceptor. Alternatively, the channel may be machined such that the depth is variable and thus, for example, shallower on the ends and deeper at the center. In the case of a curved susceptor 310, a curved or other shape showerhead may be designed to follow the curvature.

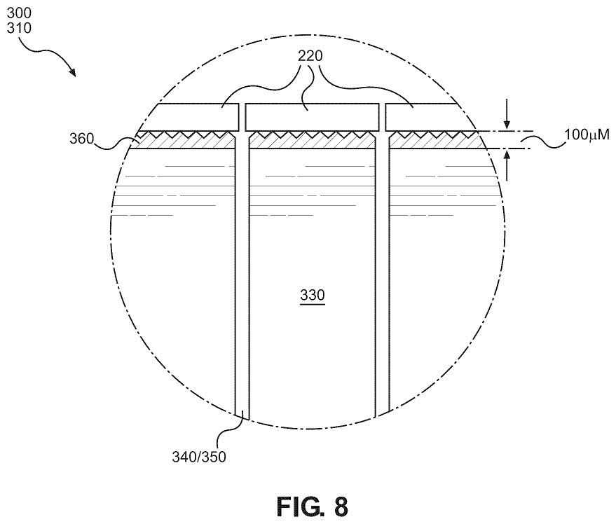

In other embodiments, top surface of raised section 330 may be textured or have protrusions 360 which may be comprised of micro-protrusions, micro-texture, surface imperfections, or gaps to aid in radiative and/or conductive heat distribution to evenly heat moving (secondary) susceptor tape 220 and consequently substrate tape 120. For example, as shown in FIG. 8, micro-texture protrusions 360 of approximately 100 microns in height are shown. Other size and density of textures are thus readily contemplated by those skilled in the art having the benefit of the present disclosure, for example, the micro-textured surface may be comprised of protrusions with an average height of 10 or even single digit microns. In yet other embodiments, the protrusions 360 may be larger such as to form micro-channels with aspect ratios (width and depth) at fractions of size smaller than channels 350 in between adjacent substrate tapes 120.

An exemplary chemical vapor deposition (CVD) reactor apparatus 700 that utilizes susceptor assemblies (200/300) described herein for controlling the temperature of a longitudinal substrate tape 120 as well as minimizing errant deposition 180 is shown in FIG. 9. In this example, CVD apparatus 700 includes reactor housing 190 which houses susceptor assembly 200 as described above and shown in FIGS. 2-5. However, it is to be understood that susceptor assembly 300 as described above and shown in FIGS. 6-8 may be installed into reactor apparatus 700 in a similar manner. Also, apparatus 700 is discussed with specific reference to a preferred embodiment of a MOCVD reactor for thin film production of HTS films. However, it is to be understood that other thin films and other deposition reactor types (e.g., CVD) may employ the susceptor assemblies (200/300) described herein.

The CVD apparatus 700 is comprised of a reactor housing 190 of a given length and width where typically the length is greater than the width where the housing 190 for HTS thin film depositions is preferably operated under vacuum conditions maintained by one or more exhaust or outflow ports 130. (The reactor's lengthwise dimension is out of the page in the 2D representation of FIG. 9.) A showerhead 150 for the delivery of one or more precursors 140, e.g., a metal organic compound from an external source (not shown) is included which may be a direct liquid injection vapor source, or a solid precursor feed system as disclosed in U.S. Pat. No. 11,162,171 which is assigned to the present Applicant and incorporated by reference herein for all purposes.

In preferred embodiments, radiation or illumination sources 160 are utilized to aid thin film growth on longitudinal substrate 120 and may be comprised of, for example, single or arrays of lamps, LEDs, etc. emitting one or more or a combination of Ultraviolet (UV) to visible wavelengths, but other wavelengths, such as near UV to far infrared bandwidth sources may be utilized. Illumination at the surface of the growing film energetically excites the surface atoms and enhances molecular surface mobility thus allowing for more rapid attainment of a lower energy configuration. In this manner, a photo-activated or photo-assisted deposition process enhances the YBCO deposition rate and improves the crystallization structure of the resulting HTS thin film. In the example of FIG. 9, lamps 160 are positioned external the reactor housing 190 and the radiation transmitted through one or more windows 165 located on one or more walls of the reactor housing 190. In other approaches, lamps 160 may be located inside the reactor housing 190. However, minimizing the distance “d” between showerhead 150 and substrate tape(s) 120 has many advantages, including higher deposition rates and efficiency. Thus, in order to provide sufficient illumination through a small gap “d” necessitates an acute angle which favors 160 placement of radiations sources 160 at further distances. It is also preferred to place the radiation source outside the reactor housing 190 to prevent the illumination source from getting coated by errant deposition which would cause degradation of the illumination power and photo-activation effectiveness. Also, externally placed sources may more easily be cooled via water-to-water heat-exchanger. Hence external sources and use of windows 165 is a preferred embodiment.

In such embodiments with reduced distance “d” between the susceptor and showerhead (e.g., as low as 20 mm, 10 mm, 5 mm, or less) in particular are provided by the present disclosure of susceptor assemblies 200/300 having a high degree of thermal control, owing in part to the heat transfer characteristics between the susceptor and proximally located showerhead 150. For example, reactor system 700 is thermally stable when it is connected to a heat source as well as a heat sink. The heat sink is the radiative heat transfer from the susceptor to the showerhead which is preferably cooled with fluid circulation, for example an oil or water circulation heat-exchanger maintained at, for example, 300-350° C. and the source is the susceptor top surface and the HTS tape. Thus, stable heat transfer from the susceptor acting as the source to the showerhead acting as the sink across reduced distance “d” may aid in improving the temperature control over the HTS tape 120. Additionally, and as discussed above, in certain embodiments, this effect may be further enhanced by selective application of emissivity adjusting coatings to various surfaces within the system, particularly the susceptor radiation shield as well as the underside surface of the showerhead facing the susceptor.

In the apparatus embodiment of FIG. 9, susceptor assembly 200 is includes secondary moving susceptor 220 which in turn supports four longitudinal substrate tapes 120. However, as discussed prior, the primary susceptor 210 may be configured to support any number of substrate tapes 120 and/or accommodate multiple passes of the same substrate tape or tapes. Substrate tape 120 payout and take-up reels (not shown) may be located inside the reactor or outside the reactor with the tape(s) passing through sealed ports located on the reactor walls of the housing 190.

CVD apparatus FIG. 9 shows susceptor assembly 200 configured to be heated by a resistive type heater as primary susceptor 210. As described above, in certain embodiments susceptor assembly 200/300 is comprised of a longitudinal (out of the page in FIG. 9) primary susceptor 210/310 heats one or more longitudinal substrate tapes 120 within the deposition apparatus 700. In the primary susceptor 210 example as shown, two heater elements 230 are coupled to susceptor block 210 with at least a portion of the heater elements 230 extending to the exterior of susceptor assembly 200 which is connected to an electrical conduit or busbar 730 that may be located inside reactor housing 190 and ultimately connects to a power source 740 external the reactor. Power source 740 may be controlled by a control system 750 with a proportional integral derivative (PID) or other type of feedback controller capable of receiving inputs from one or more sensors 760 such as a direct contact thermocouples or a non-contact infra-red thermometer, comparing the measured temperature to a predetermined setpoint temperature, and adjusting the power input to the primary susceptor block via power source 740.

Also, the susceptor assembly 200/300 may include one or more refractory elements 240/244 that are positioned adjacent to a side of the primary susceptor block 210/310, a lower refractory element 242 for support, as well as a radiation shield 246 surrounds one or more sides of the refractory element(s) 240/244.

CVD apparatus 700 may be further characterized by the additional features described herein to include but not limited to the following regarding either susceptor assemblies 200 or 300 as discussed above and illustrated in FIGS. 2-8:

The refractory element(s) 240/242/244 may be composed of a single or more than one component or material. The components of the refractory element(s) 240/242/244 may be further comprised of at least one material that is different from a material of another component.

An emissivity coating 248/249 may be applied to one or more portions and/or sides internal or external of radiation shield 250.

The emissivity coating may be applied to additional reactor apparatus 700 components e.g., the showerhead 150.

The emissivity coating may be a low emissivity or high emissivity coating, e.g., a ceramic or black body coating.

The top surface of the primary susceptor 210/310 may be curved in a lengthwise direction such that the vertical height of the susceptor is greater at the center to provide tension to the longitudinal substrate tape 120.

Primary susceptor blocks 210 and 310 may include protrusions 360, which are inclusive of micro-protrusions, texture, micro-texture, gaps or surface imperfections to aid conductive heat distribution to aid in evenly heat the longitudinal substrate tape 120.

Protrusions 360 may additionally form micro-channels beneath the longitudinal substrate tapes 120.

Protrusions 360 may run continuously down the length of a primary susceptor 210/310 or may include breaks in the longitudinal direction thus creating grids of various patterns.

What is claimed is:

1. A susceptor assembly (200/300) for heating and temperature control of one or more longitudinal substrate tapes (120) within a deposition apparatus, the susceptor assembly (200/300) comprising:
a primary susceptor (210/310) for heating at least one longitudinal substrate tape (120);
a secondary susceptor (220) disposed between the primary susceptor (210) and the longitudinal substrate tape (120); and
wherein the secondary susceptor (220) is configured as a longitudinal tape having a width greater than a substrate tape (120).

2. The susceptor assembly of claim 1, wherein the primary susceptor (210/310) is stationary and the secondary susceptor (220) translates across the top of the primary susceptor and underneath the longitudinal substrate tape (120) in a lengthwise direction relative to the longitudinal substrate tape (120).

3. The susceptor assembly of claim 1, wherein the primary susceptor (210/310) is comprised of a resistive type heater coupled to at least one heater element (230).

4. The susceptor assembly of claim 1, further comprising a refractory element (240/242/244) positioned adjacent to a side of the primary susceptor (210/310) and a radiation shield (246) encloses one or more sides of the refractory element.

5. The susceptor assembly of claim 4, further comprising a radiation shield (246) encloses one or more sides of the refractory element.

6. A susceptor assembly (300) for heating and temperature control of one or more longitudinal substrate tapes (120) within a deposition apparatus, the susceptor assembly (200/300) comprising:
a primary susceptor (310) for heating more than one longitudinal substrate tape (120) comprised of two or more adjacent raised sections (330) extending vertically from the upper surface of the primary susceptor block (310) wherein each raised section is configured to heat a separate longitudinal substrate tape (120), wherein each raised section (330) is separated by a gap (340) from an adjacent raised section (330), wherein the gap (340) separating adjacent raised sections (330) forms a channel (350) to collect errant deposition material (180) from between adjacent longitudinal substrate tapes (120);
a secondary susceptor (220) disposed between the primary susceptor (310) and the longitudinal substrate tape (120); and
wherein the secondary susceptor (220) is configured as a longitudinal tape having a width greater than a substrate tape (120).

7. The susceptor assembly of claim 6, wherein the primary susceptor (310) is stationary and the secondary susceptor (220) translates across the top of the primary susceptor and underneath the longitudinal substrate tape (120) in a lengthwise direction relative to the longitudinal substrate tape (120).

8. The susceptor assembly of claim 6, wherein the primary susceptor (310) is comprised of a resistive type heater coupled to at least one heater element (230).

9. The susceptor assembly of claim 6, further comprising a refractory element (240/242/244) positioned adjacent to a side of the primary susceptor (310) and a radiation shield (246) encloses one or more sides of the refractory element.

10. The susceptor assembly of claim 9, further comprising a radiation shield (246) adjacent one or more external sides of the refractory element.

11. A chemical vapor deposition (CVD) apparatus (700) for deposition of thin films on a longitudinal substrate tape (120), the apparatus (700) comprising:
a reactor housing (190) having an inlet showerhead (150) for introducing a precursor (140), a vacuum exhaust (130); and an illumination source (160);
a susceptor assembly (200/300) located within the reactor housing (720) comprising a primary susceptor (210/310) for heating at least one longitudinal substrate tape (120), a secondary susceptor (220) disposed between the primary susceptor (210/310) and the longitudinal substrate tape (120), and wherein the secondary susceptor (220) is configured as a longitudinal tape having a width greater than a longitudinal substrate tape (120); and
wherein the primary susceptor (210/310) is stationary and the secondary susceptor (220) translates in a lengthwise direction relative to the longitudinal substrate tape (120), and
wherein the longitudinal substrate tape (120) is configured to translate above the secondary susceptor (210) and below the inlet showerhead (150).

12. The CVD apparatus of claim 11, wherein the primary susceptor 210/310 is comprised of a resistive type heater coupled to at least one heater element (230).

13. The susceptor assembly of claim 11, further comprising a refractory element (240/242/244) positioned adjacent to a side of the primary susceptor (310) and a radiation shield (246) encloses one or more sides of the refractory element.

14. The susceptor assembly of claim 13, further comprising a radiation shield (246) adjacent one or more external sides of the refractory element.

15. The CVD apparatus of claim 11, wherein the primary susceptor (310) is further comprised of two or more adjacent raised sections (330) extending vertically from the upper surface of the primary susceptor (310) wherein each raised section is configured to heat a separate longitudinal substrate tape (120), and
wherein each raised section (330) is separated by a gap (340) from an adjacent raised section (330), and
wherein the gap (340) separating adjacent raised sections (330) forms a channel (350) to collect errant deposition material (180) from between adjacent longitudinal substrate tapes (120).

16. The CVD apparatus of claim 15, wherein the susceptor assembly (200/300) further comprises a refractory element (240/242/244) positioned adjacent to a side of the primary susceptor (210/310),

17. The CVD apparatus of claim 16, further comprising a radiation shield (246) adjacent one or more external sides of refractory element (240/242/244).

18. The CVD apparatus of claim 11, wherein the susceptor assembly is configured to heat more than one longitudinal substrate tape.

19. The CVD apparatus of claim 11, wherein the illuminated source is located exterior the reactor housing 190.

20. The CVD apparatus of claim 11, wherein the vertical spacing between the inlet showerhead (150) and the longitudinal substrate tape (120) is less than 50 mm.
